(19) United States
(12) Patent Application Publication
(10) Pub. No.: US 2007/0190768 A1
(43) Pub. Date: Aug. 16, 2007

(54) Manufacturing method of semiconductor device

(76) Inventors: Motoyuki Sato, Yokohama-shi (JP); Tomonori Aoyama, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/699,396

(22) Filed: Jan. 30, 2007

(30) Foreign Application Priority Data
Jan. 31, 2006 (JP) 2006-023838
Nov. 29, 2006 (JP) 2006-322101

(51) Int. Cl. H01L 21/4763

(52) U.S. Cl. 438/592; 438/299

(57) ABSTRACT

A method of manufacturing a semiconductor device, includes forming a gate insulating film on a semiconductor substrate, and forming a gate electrode on the gate insulting film, wherein forming the gate insulating film includes forming a metal silicate film, and a silicon source used for forming the metal silicate film includes at least one of a first hydrocarbon silicon compound obtained by replacing at least one of hydrogen atoms in monosilane with an alkyl group, a second hydrocarbon silicon compound obtained by replacing at least one of hydrogen atoms in disilane with an alkyl group, and a third hydrocarbon silicon compound obtained by replacing at least one of hydrogen atoms in trisilane with an alkyl group.

### CROSS-REFERENCE TO RELATED APPLICATIONS

This application is based upon and claims the benefit of priority from prior Japanese Patent Applications No. 2006-023838, filed Jan. 31, 2006; and No. 2006-322101, filed Nov. 29, 2006, the entire contents of both of which are incorporated herein by reference.

### BACKGROUND OF THE INVENTION

1. Field of the Invention

The present invention relates to a manufacturing method of a semiconductor device.

2. Description of the Related Art

Along with miniaturization of a semiconductor device, there is an increasing demand for a reduction in thickness of a gate insulating film. However, when the thickness of a silicon oxide film or silicon nitride film that has conventionally been used is reduced, a leakage current is increased, thus restricting the film thickness reduction.

In light of the above, there is proposed that a metal silicate film (e.g., Hf-silicate film) having a relative dielectric constant higher than that of the silicon oxide film or silicon nitride film is used as a gate insulating film (refer to, e.g., Jpn. Pat. Appln. KOKAI Publication No. 2003-204061). By using an insulating film having a high dielectric constant, it is possible to increase the physical film thickness of the gate insulating film, thereby reducing a leakage current.

A CVD process such as an MOCVD is generally used to form the metal silicate film. A silicon source used in the CVD process includes an amine compound such as tetradimethylamino silicon or tridimethylamino silicon, or an alkoxide compound such as TEOS. However, the decomposition efficiencies of the above silicon sources are low, so that nitrogen or carbon contained in the silicon source may be introduced into the silicate film as impurity. This may result in an increase of the leakage current or occurrence of a fixed charge, causing degradation of the characteristics and reliability of a semiconductor device.

As described above, there is proposed that a metal silicate film having a high dielectric constant is used as a gate insulating film. However, the decomposition efficiency of the silicon source is low, so that nitrogen or carbon is introduced into the metal silicate film as impurity, making it difficult to obtain a semiconductor device excellent in the characteristics and reliability.

Further, along with the miniaturization of a semiconductor device, a reduction in resistance and inhibition of depletion of a gate electrode are required. To meet such a request, there is proposed that a metal silicide film is used as a gate electrode.

In the case where a CVD process is used to form the metal silicide film, dimethylaminosilane or the like is generally used as a silicon source. However, the decomposition efficiencies of the above silicon sources are low, so that carbon contained in the silicon source may be introduced into the silicide film as impurity. This may degrade controllability of the work function of the gate electrode, causing degradation of the characteristics and reliability of a semiconductor device.

### BRIEF SUMMARY OF THE INVENTION

A first aspect of the present invention, there is provided a method of manufacturing a semiconductor device, comprising: forming a gate insulating film on a semiconductor substrate; and forming a gate electrode on the gate insulting film, wherein forming the gate insulating film includes forming a metal silicate film, and a silicon source used for forming the metal silicate film includes at least one of a first hydrocarbon silicon compound obtained by replacing at least one of hydrogen atoms in monosilane with an alkyl group, a second hydrocarbon silicon compound obtained by replacing at least one of hydrogen atoms in disilane with an alkyl group, and a third hydrocarbon silicon compound obtained by replacing at least one of hydrogen atoms in trisilane with an alkyl group.

A second aspect of the present invention, there is provided a method of manufacturing a semiconductor device, comprising: forming a gate insulating film on a semiconductor substrate; and forming a gate electrode on the gate insulting film, wherein forming the gate electrode includes forming a metal silicide film, and a silicon source used for forming the metal silicide film includes at least one of a first hydrocarbon silicon compound obtained by replacing at least one of hydrogen atoms in monosilane with an alkyl group, a second hydrocarbon silicon compound obtained by replacing at least one of hydrogen atoms in disilane with an alkyl group, and a third hydrocarbon silicon compound obtained by replacing at least one of hydrogen atoms in trisilane with an alkyl group.

### BRIEF DESCRIPTION OF THE SEVERAL VIEWS OF THE DRAWING

FIG. 1 is a cross-sectional view schematically showing a structure of a semiconductor device according to first and second embodiments of the present invention;

FIG. 2 relates to the first embodiment and schematically shows a film formation apparatus for forming a metal silicate film;

FIG. 3 relates to the first and second embodiments and shows chemical formulas of a silicon source used for formation of a metal silicate film and metal silicide film;

FIG. 4 is a view showing a carbon concentration in the metal silicate film in the cases where diethylsilane and tetradimethylamino silicon are used as the silicon sources;

FIG. 5 is a view showing a nitrogen concentration in the metal silicate film in the cases where diethylsilane and tetradimethylamino silicon are used as the silicon sources;

FIG. 6 is a view showing carrier trap density in the metal silicate film in the cases where diethylsilane and tetradimethylamino silicon are used as the silicon sources;

FIG. 7 is a view showing a measurement result of a deterioration test in the cases where diethylsilane and tetradimethylamino silicon are used as the silicon source;

FIG. 8 is a view showing a difference between a threshold voltage obtained in the case where an Hf silicate film is used as the gate insulating film and threshold voltage obtained in the case where a silicon dioxide film is used as the gate insulating film;

FIG. 9 is a cross-sectional view schematically showing a structure of the semiconductor device according to a modification of the first embodiment; and

FIG. 10 relates to the second embodiment and schematically shows a film formation apparatus for forming a metal silicate film.

### DETAILED DESCRIPTION OF THE INVENTION

Hereinafter, embodiments of the present invention will be described with reference to the accompanying drawings.

### First Embodiment

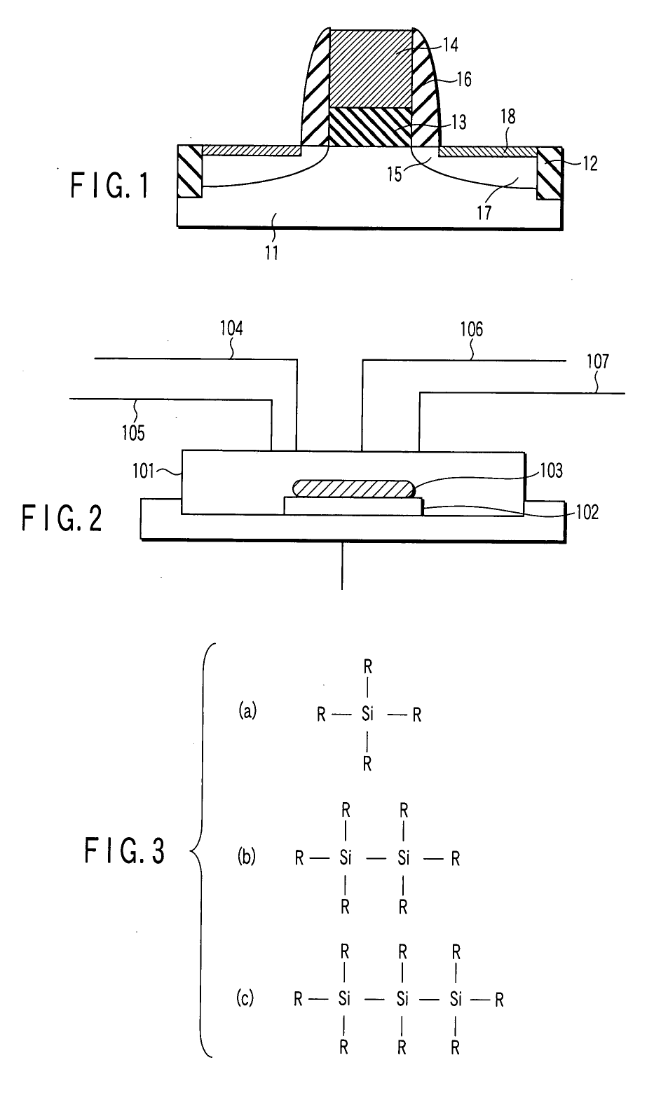

FIG. 1 is a cross-sectional view schematically showing a structure of a semiconductor device (MIS transistor) according to a first embodiment of the present invention.

A manufacturing method of the semiconductor device shown in FIG. 1 will briefly be described below. An isolation region 12 is formed in the surface region of a silicon substrate (semiconductor substrate) 11. Subsequently, a gate insulating film 13 is formed on the silicon substrate 11 and a gate electrode 14 is formed on the gate insulating film 13. Subsequently, after a shallow impurity diffusion layer 15 which becomes a source/drain region is formed, a side wall insulating portion 16 is formed on the side surface of the gate insulating film 13 and gate electrode 14. Further, after a deep impurity diffusion layer 17 which becomes a source/drain region is formed, a silicide film (salicide film) 18 is formed on the surface of the source/drain region. In this manner, the semiconductor device shown in FIG. 1 is obtained.

The details of the formation method of the gate insulating film 13 will next be described.

In the present embodiment, the gate insulating film 13 is formed of a metal silicate film. Silicon, oxygen, and a metal element are contained in the metal silicate film. A hafnium (Hf) silicate film, a zirconium (Zr) silicate film, an aluminum (Al) silicate film, a tantalum (Ta) silicate film, or a lanthanum (La) silicate film can be used as the metal silicate film. In the present embodiment, a hafnium (Hf) silicate film is used. The hafnium (Hf) silicate film has high heat resistance and high carrier mobility and, therefore, has great potential as the gate insulating film 13.

FIG. 2 is a view schematically showing a film formation apparatus for forming the metal silicate film. A susceptor 102 is provided in a film formation chamber 101, and a wafer 103 is placed on the susceptor 102. A silicon source supply line 104, a metal source supply line 105, an oxidizer supply line 106, and an inert gas supply line 107 are connected to the chamber 101.

In forming the metal silicate film, the wafer (substrate) 103 is placed on the susceptor 102 and is heated by the susceptor 102. The heating temperature is, e.g., 600° C. A resistance heating method or an induction heating method using an inductive coil can be used for the heating of the wafer 103. After the wafer 103 is placed on the susceptor 102, a silicon source, a metal source, and an oxidizer (oxidizing agent) are simultaneously supplied into the chamber 101 through the silicon source supply line 104, metal source supply line 105, and-oxidizer supply line 106. These gases may alternately be supplied.

An amine compound can be used as the metal source (hafnium (Hf) source, in the case of the present embodiment). Alternatively, a halogen compound such as a chloride or an alkoxide compound such as hafnium-tertiarybuthoxide can be used as the metal source. Oxygen (O₂), ozone (O₃), nitric oxide (NO), nitrous oxide (N₂O) or oxygen radical of these gases can be used as the oxidizer.

As the silicon source, at least one of a hydrocarbon silicon compound (A1) obtained by replacing at least one of the hydrogen atoms in monosilane (SiH₄) with an alkyl group, hydrocarbon silicon compound (A2) obtained by replacing at least one of the hydrogen atoms in disilane (Si₂H₆) with an alkyl group, and hydrocarbon silicon compound (A3) obtained by replacing at least one of the hydrogen atoms in trisilane (Si₃H₈) with an alkyl group can be used.

The above hydrocarbon silicon compounds A1, A2, and A3 can be represented by general formulas shown in FIGS. 3(a) to 3(c), respectively. R is bonded to silicon (Si) and can be represented by a general formula CₙH₂ₙ₊₁ (C is carbon, H is hydrogen, and n is zero or positive integer). When n is a positive integer, R is an alkyl group such as CH₃ (methyl group), C₂H₅ (ethyl group), C₃H₇ (propyl group), or C₄H₉ (butyl group). When n is zero, R is H (hydrogen). In each of FIGS. 3(a) to 3(c), at least one R should be an alkyl group (R which is not an alkyl group is hydrogen). Further, in each of FIGS. 3(a) to 3(c), the same alkyl groups may be bonded to silicon, or two or more different alkyl groups may be bonded to silicon.

For example, the hydrocarbon silicon compound A1 may be monomethylsilane, dimethylsilane, trimethylsilane, tetramethylsilane, monoethylsilane, diethylsilane, triethylsilane, tetraethylsilane, monopropylsilane, dipropylsilane, tripropylsilane, tetrapropylsilane, monobutylsilane, dibutylsilane, tributylsilane, and tetrabutylsilane. In the present embodiment, diethylsilane is used.

As a source decomposition method, a thermal decomposition method, a remote plasma method, an In-situ plasma method can be used. That is, as a method of forming the metal silicate film, a CVD (Chemical vapor deposition) process such as a thermal CVD or plasma CVD can be used. The film formation temperature in the thermal CVD process is preferably at 300° C. or more. Further, an ALD (atomic layer deposition) method using chemical adsorption can be used to form the metal silicate film.

To evaporate the source material, a method of supplying the source material onto a heated plate can be taken as an example. Alternatively, a method of supplying bubbling inert gas into a source material vessel while the vessel is being heated can be employed. The inert gas may be supplied into the source material vessel by its own pressure. The silicon source, metal source, and oxidizer may be mixed in a manifold provided on the upstream side of the film formation chamber or in the film formation chamber.

The film formation of the metal silicate film has been described above. The hydrocarbon silicon compound shown in FIG. 3 is used as the silicon source. This hydrocarbon silicon compound has a higher decomposition efficiency than that of a conventional silicon source (amine compound, etc.). As described above, in the case where the conventional silicon source is used, since the decomposition efficiency thereof is low, nitrogen or carbon contained in the silicon source may be introduced into the metal silicate film as impurity. This may result in an increase of the leakage current or occurrence of a fixed charge. However, the hydrocarbon silicon compound having a high decomposition efficiency is used as the silicon source in the present embodiment, so that the above problem can be prevented.

Further, the conventional silicon source has a lower decomposition efficiency than that of the metal source (e.g., amine compound used as an Hf source), so that it has been difficult to increase the ratio of silicon in the metal silicate film. Assuming that the metal silicate film is represented by MₓSi₁₋ₓO₂ (M is metal element such as Hf and 0<x<1), it has conventionally been difficult to reduce the value of x. Since the hydrocarbon silicon compound having a high decomposition efficiency is used as the silicon source in the present embodiment, it is possible to control the value of x to a desired value from 0 to 1. For example, by controlling the film formation temperature, pressure of film formation atmosphere, ratio between the supply of the silicon source and supply of the metal source, gas flow rate, or the like, the x value can be controlled to a desired value from 0 to 1.

Nitriding may be applied to the metal silicate film. The application of nitriding allows an increase of a dielectric constant, inhibition of crystallization, inhibition of penetration of boron (B) in a P-type MIS transistor. As a result, it is possible to obtain advantages such as stabilization of a threshold voltage, reduction of a leakage current, inhibition of carrier trap, or increase in the stability of an operating current. A plasma process can be used to apply the nitriding. Alternatively, a thermal nitriding technique of supplying ammonia onto a heated wafer may be used to perform nitriding. Further, a radical nitriding process can be used. By applying annealing treatment after the nitriding, it is possible to achieve advantages such as a reduction of a fixed charge or inhibition of carrier trap.

The gate electrode formed on the gate insulating film will next be described. A polysilicon film can be used as the gate electrode. The polysilicon film can be formed by a CVD or sputtering method. A metal film may be used as the gate electrode. The metal film can also be formed by the CVD or sputtering method. Further, the gate electrode may be formed by patterning of a gate electrode film or may be formed using a damascene method.

Evaluation results obtained in the case where the hydrocarbon silicon compound is used as the silicon source of the metal silicate film will next be described. In either case, the Hf silicate film is used as the metal silicate film.

FIGS. 4 and 5 show a measurement result of carbon concentration in the metal silicate film (Hf silicate film) (FIG. 4) and a measurement result of nitrogen concentration in the metal silicate film (FIG. 5) in the case where diethylsilane which is a hydrocarbon silicon compound is used as the silicon source. Tetradiethylaminohafnium which is an amine compound is used as the metal source. The concentration ratio between the hafnium (Hf) and silicon (Si) in the metal silicate film is Hf/Si=3/7. As a comparative example, a measurement result obtained in the case where tetradimethylamino silicon which is amine compound is used as the silicon source is shown in FIGS. 4 and 5. Except for the silicon source and source material supply ratio, the above measurements of the present embodiment and comparative example were performed under the same basic film formation conditions (film formation temperature, pressure of film formation atmosphere, and gas supply amount).

As shown in FIG. 4, in the case (comparative example) where tetradimethylamino silicon is used as the silicon source, the carbon impurity concentration in the metal silicate film is about 3E20 (atoms/cm³). On the other hand, in the case (present embodiment) where diethylsilane is used as the silicon source, the carbon impurity concentration in the metal silicate film is less than specified detection limit (1E19 (atoms/cm³)). Thus, by using diethylsilane as the silicon source, the carbon impurity concentration in the metal silicate film can significantly be reduced.

As shown in FIG. 5, in the case (comparative example) where tetradimethylamino silicon is used as the silicon source, the nitrogen impurity concentration in the metal silicate film is about 1E21 (atoms/cm³). On the other hand, in the case (present embodiment) where diethylsilane is used as the silicon source, the nitrogen impurity concentration in the metal silicate film is about 7E19 (atoms/cm³). Thus, by using diethylsilane as the silicon source, the nitrogen impurity concentration in the metal silicate film can significantly be reduced.

The above reduction effect of the impurity concentration is due to high decomposition efficiency of the hydrocarbon silicon compound. In the case where the conventional silicon source (amine compound, etc.) is used, since the decomposition efficiency thereof is low, nitrogen and carbon bonded to silicon are not decomposed but taken in the metal silicate film. As a result, the impurity concentration in the metal silicate film is increased. On the other hand, in the present embodiment, the hydrocarbon silicon compound having a high decomposition efficiency is used, so that the impurity is easily gasified and removed. As a result, it is possible to significantly reduce the impurity concentration in the metal silicate film.

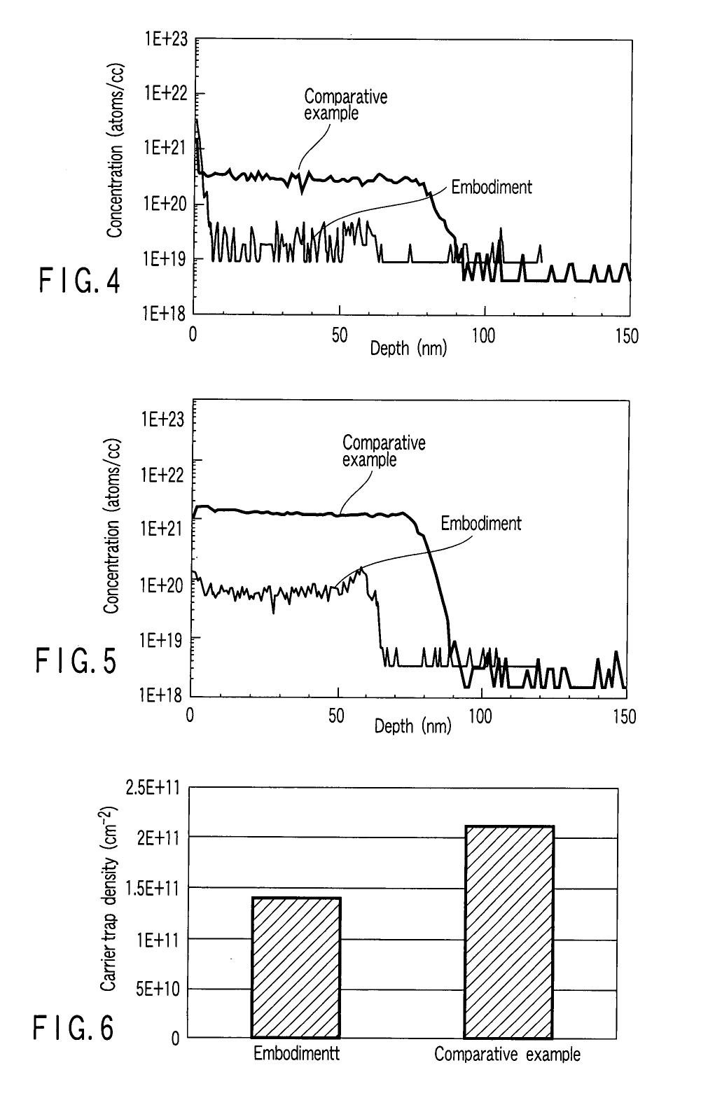

FIG. 6 is a view showing a measurement result of carrier trap density in the metal silicate film (Hf silicate film). The film formation gas and film formation condition of the above measurement were the same as those in the measurements shown in FIGS. 4 and 5. As is clear from FIG. 6, in the case (embodiment) where diethylsilane is used as the silicon source, the trap density is significantly reduced as compared to the case (comparative example) where the tetradimethylamino silicon is used as the silicon source. When the trap density is thus reduced, stabilization of a threshold voltage or inhibition of Coulomb scattering due to a fixed charge can be achieved.

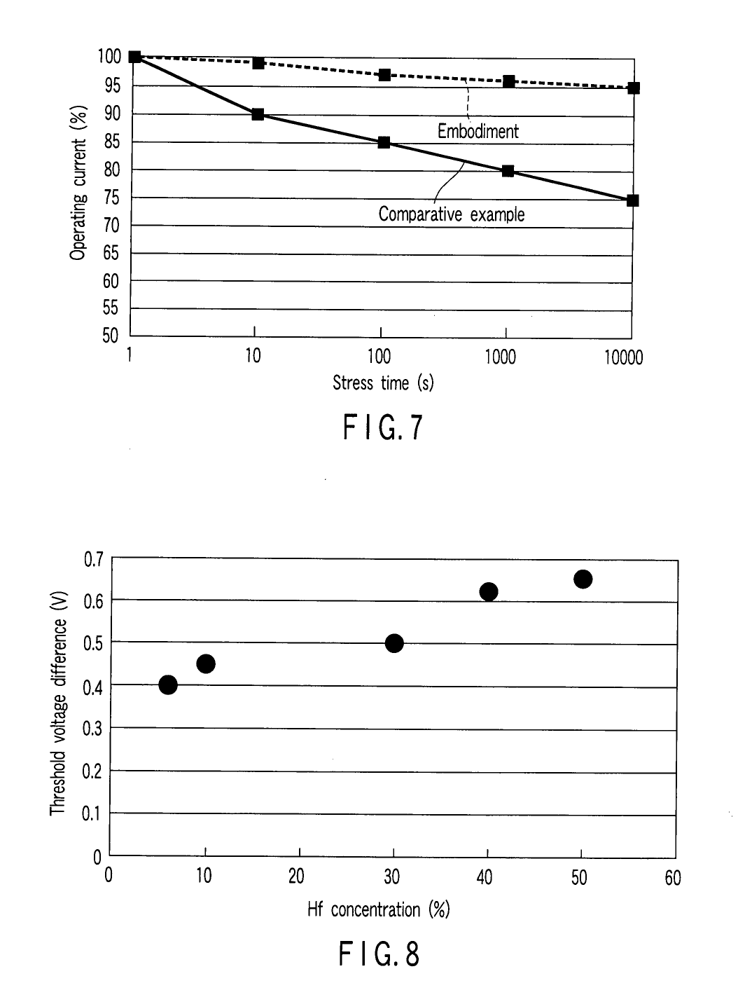

Further, the reduction of the trap density contributes to prevention of deterioration of the semiconductor device also in a deterioration test under high temperature and high stress. FIG. 7 is a view showing a measurement result of a deterioration test. As is clear from FIG. 7, in the case (embodiment) where diethylsilane is used as the silicon source, a reduction of an operating current is significantly suppressed as compared to the case (comparative example) where the tetradimethylamino silicon is used as the silicon source. Thus, by using a hydrocarbon silicon compound such as diethylsilane is used as the silicon source, it is possible to significantly reduce characteristics deterioration.

In the case where the metal silicate film is used as a gate insulating film, it is difficult to obtain a desired threshold voltage due to a variation of the Fermi level energy. Particularly, in a P-type MIS transistor, in the case where an Hf silicate is used as a gate insulating film, a threshold voltage is shifted by about 600 mV in the positive direction, as compared to the case where silicon dioxide is used as a gate insulating film, resulting in significant reduction of the transistor operating current. Conventionally, a silicon source having a lower decomposition efficiency than that of a metal source (Hf source) has been used to form an Hf silicate film. Therefore, the ratio of Hf relative to Si is increased, making it difficult to form an Hf silicate film whose Hf composition is less than 20%. On the other hand, in the case where the hydrocarbon silicon compound of the present embodiment is used as the silicon source, since the decomposition efficiency thereof is high, it is possible to form an Hf silicate film whose Hf composition is less than 20%.

FIG. 8 is a view showing, with regard to a P-type MIS transistor, a difference between a threshold voltage obtained in the case where an Hf silicate film is used as the gate insulating film and threshold voltage obtained in the case where a silicon dioxide film (SiO₂ film) is used as the gate insulating film. The larger the threshold voltage difference becomes, the smaller the operating current becomes. Therefore, a smaller threshold voltage difference is preferable in terms of the operating current.

As is clear from FIG. 8, the lower the Hf concentration (Hf composition) becomes, the smaller the threshold voltage difference becomes. Particularly, when the Hf concentration becomes less than 10%, the threshold voltage difference becomes less than about 450 mV. As a result, it is possible to significantly increase the operating current of the P-type MIS transistor. In the case where diethylsilane is used as the silicon source and tetradiethylaminohafnium (TDEAH) is used as the metal source (Hf source), by setting the film formation temperature at 600° C. and a pressure of film formation atmosphere at more than 5 Torr, it is possible to reduce the Hf concentration in the metal silicate to less than 10%.

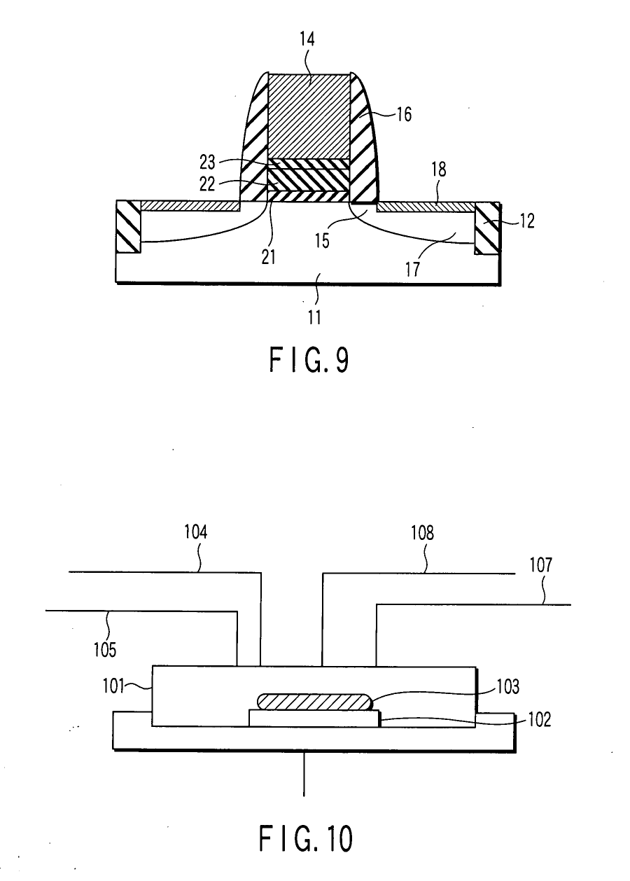

FIG. 9 is a cross-sectional view schematically showing a structure of the semiconductor device (MIS transistor) according to a modification of the present embodiment. As described above, in the case-where a hydrocarbon silicon compound is used as the silicon source, since the decomposition efficiency thereof is high, it is possible to form a metal silicate film whose metal concentration is low. The present modification relates to a MIS transistor produced by utilizing such characteristics. The basic structure and manufacturing method in FIG. 9 are the same as in the MIS transistor of FIG. 1. Therefore, the same reference numerals as FIG. 1 are given to the components which correspond to those in FIG. 1, and the detailed descriptions are omitted.

As shown in FIG. 9, in the MIS transistor according to the present modification, a gate insulating film is formed of an interface insulating film 21, a lower metal silicate film 22, and an upper metal silicate film 23. The interface insulating film 21 is for increasing the characteristics of the interface between the silicon substrate 11 and gate insulating film and is not necessarily provided. The metal concentration of the upper metal silicate film 23 is lower than that of the lower metal silicate film 22. In the case where an Hf silicate film is used as the lower metal silicate film 22 and upper metal silicate film 23, the Hf concentration (Hf composition) of the upper metal silicate film 23 is less than 10% and the Hf concentration (Hf composition) of the lower metal silicate film 22 is more than 50%.

As described above, a hydrocarbon silicon compound such as diethylsilane has a high decomposition efficiency. Therefore, when such a hydrocarbon silicon compound is used as the silicon source, it is possible to set the metal concentration (metal composition) in the metal silicate film to a desired value. Based on such characteristics, in the present modification, a stacked film of the lower metal silicate film 22 having a high Hf concentration and upper metal silicate film 23 having a low Hf concentration is formed.

The lower metal silicate film 22 has a high metal concentration (Hf concentration) and, therefore, has a high dielectric constant. Therefore, the dielectric constant of the gate insulating film cam be increased. As a result, the thickness of the gate insulating film can be increased, which is effective for a reduction of a leakage current. On the other hand, the upper metal silicate film 23 has a low metal concentration (Hf concentration), so that a variation in Fermi level energy is small. Therefore, a variation in a threshold voltage becomes small, which is effective for suppression of a reduction in the operating current. Thus, the use of the stacked film of the lower metal silicate film 22 and upper metal silicate film 23 allows a reduction of leakage current and increase of the operating current to be achieved at the same time.

As described above, in the present embodiment, as the silicon source used in the formation of the metal silicate film, a first hydrocarbon silicon compound obtained by replacing at least one of the hydrogen atoms in monosilane with an alkyl group, a second hydrocarbon silicon compound obtained by replacing at least one of the hydrogen atoms in disilane with an alkyl group, or a third hydrocarbon silicon compound obtained by replacing at least one of the hydrogen atoms in trisilane with an alkyl group is used. These hydrocarbon silicon compounds have a high decomposition efficiency. Therefore, it is possible to prevent the impurity such as carbon contained in the silicon source from being introduced into the metal silicate film. This results in a reduction of the carrier trap density and a leakage current, thereby obtaining a semiconductor device excellent in characteristics and reliability.

Further, since the hydrocarbon silicon compound having a high decomposition efficiency is used as the silicon source in the present embodiment, it is possible to increase the silicon concentration (silicon ratio) in the metal silicate film as compared to a conventional approach. In other words, it is possible to decrease the metal concentration (metal ratio) in the metal silicate film as compared to a conventional approach. The reduction of the metal concentration, which has conventionally been difficult to be achieved, can thus be achieved, so that it is possible to set the composition ratio between silicon and a metal element in the metal silicate film to a desired value. Therefore, a metal silicate film having desired and adequate characteristics can be formed. Also based on this standpoint, it is possible to obtain a semiconductor device excellent in characteristics and reliability.

### Second Embodiment

A semiconductor device (MIS transistor) according to a second embodiment of the present invention will be described.

The basic structure of the semiconductor device according to the second embodiment and basic manufacturing method thereof are the same as those of the semiconductor device according to the first embodiment shown in FIG. 1, and the detailed descriptions thereof are omitted here.

The details of the formation method of a gate electrode 14 (refer to FIG. 1) will next be described.

In the present embodiment, the gate electrode 14 is formed of a metal silicide film. Silicon and a metal element are contained in the metal silicide film. In addition to silicon and metal element, Nitrogen (N) may be contained in the metal silicide film. Specifically, a hafnium (Hf) silicide film, a zirconium (Zr) silicide film, a tantalum (Ta) silicide film, a titanium (Ti) silicide film, a ruthenium (Ru) silicide film, or a tungsten (W) silicide film can be used as the metal silicide film. Nitrogen (N) may be contained in the above silicide film. In the present embodiment, a tantalum silicide film (TaSi) or a tantalum silicide film containing nitrogen (TaSiN) is used as the metal silicide film.

FIG. 10 is a view schematically showing a film formation apparatus for forming the metal silicide film. The basic configuration of the film formation apparatus shown in FIG. 10 is the same as that according to the first embodiment shown in FIG. 2. That is, the susceptor 102 is provided in the film formation chamber 101, and a wafer 103 is placed on the susceptor 102. A silicon source supply line 104, a metal source supply line 105, a nitrogen source supply line 108, and inert gas supply line 107 are connected to the chamber 101.

In forming the metal silicide film, the wafer (substrate) 103 is placed on the susceptor 102 and is heated by the susceptor 102. The heating temperature is, e.g., 600° C. A resistance heating method or an induction heating method using an inductive coil can be used for the heating of the wafer 103. After the wafer 103 is placed on the susceptor 102, source gases are simultaneously supplied into the chamber 101 through the respective source material supply lines. These gases may alternately be supplied.

An amine compound can be used as the metal source. Alternatively, a halogen compound such as a chloride can be used as the metal source. Ammonia (NH₃) can be used as the nitrogen source.

As the silicon source, at least one of a hydrocarbon silicon compound (A1) obtained by replacing at least one of the hydrogen atoms in monosilane (SiH₄) with an alkyl group, hydrocarbon silicon compound (A2) obtained by replacing at least one of the hydrogen atoms in disilane (Si₂H₆) with an alkyl group, and hydrocarbon silicon compound (A3) obtained by replacing at least one of the hydrogen atoms in trisilane (Si₃H₈) with an alkyl group can be used.

As in the case of the first embodiment, the above hydrocarbon silicon compounds A1, A2, and A3 can be represented by general formulas shown in FIGS. 3(a) to 3(c), respectively. R is bonded to silicon (Si) and can be represented by a general formula CₙH₂ₙ₊₁ (C is carbon, H is hydrogen, and n is zero or positive integer). When n is a positive integer, R is an alkyl group such as CH₃ (methyl group), C₂H₅ (ethyl group), C₃H₇ (propyl group), or C₄H₉ (butyl group). When n is zero, R is H (hydrogen). In each of FIGS. 3(a) to 3(c), at least one R should be an alkyl group (R which is not an alkyl group is hydrogen). Further, in each of FIGS. 3(a) to 3(c), the same alkyl groups may be bonded to silicon, or two or more different alkyl groups may be bonded to silicon.

For example, the hydrocarbon silicon compound A1 may be monomethylsilane, dimethylsilane, trimethylsilane, tetramethylsilane, monoethylsilane, diethylsilane, triethylsilane, tetraethylsilane, monopropylsilane, dipropylsilane, tripropylsilane, tetrapropylsilane, monobutylsilane, dibutylsilane, tributylsilane, and tetrabutylsilane. In the present embodiment, diethylsilane is used.

As a source decomposition method, a thermal decomposition method, a remote plasma method, an In-situ plasma method can be used. That is, as a method of forming the metal silicide film, a CVD (Chemical vapor deposition) process such as a thermal CVD or plasma CVD can be used. The film formation temperature in the thermal CVD process is preferably at 300° C. or more. Further, an ALD (atomic layer deposition) method using chemical adsorption can be used to form the metal silicide film.

To evaporate the source material, a method of supplying the source material onto a heated plate can be taken as an example. Alternatively, a method of supplying bubbling inert gas into a source material vessel while the vessel is being heated can be employed. The inert gas may be supplied into the source material vessel by its own pressure. The source materials may be mixed in a manifold provided on the upstream side of the film formation chamber or in the film formation chamber.

The film formation of the metal silicide film has been described above. The hydrocarbon silicon compound shown in FIG. 3 is used as the silicon source. This hydrocarbon silicon compound has a higher decomposition efficiency than that of a conventional silicon source (amine compound, etc.). As described above, in the case where the conventional silicon source is used, since the decomposition efficiency thereof is low, carbon contained in the silicon source may be introduced into the metal silicide film as impurity. This may degrade controllability of the work function of the gate electrode. However, the hydrocarbon silicon compound having a high decomposition efficiency is used as the silicon source in the present embodiment, so that the above problem can be prevented.

Further, the conventional silicon source has a lower decomposition efficiency than that of the metal source (e.g., amine compound), so that it has been difficult to increase the ratio of silicon in the metal silicide film. Since the hydrocarbon silicon compound having a high decomposition efficiency is used as the silicon source in the present embodiment, it is possible to obtain a desired silicon ratio. For example, by controlling the film formation temperature, pressure of film formation atmosphere, ratio between the supply of the silicon source and supply of the metal source, gas flow rate, or the like, it is possible to obtain a desired silicon ratio.

Evaluation results obtained in the case where the hydrocarbon silicon compound is used as the silicon source of the metal silicide film will next be described.

The carbon impurity concentration in a tantalum silicide film (TaSi) as the metal silicide film was measured. In the case (comparative example) where dimethylaminosilane which is an amine compound is used as the silicon source, the carbon impurity concentration in the TaSi film is about 1E20 (atoms/cm³) or more. On the other hand, in the case (embodiment) where diethylsilane which is a hydrocarbon silicon compound is used as the silicon source, the carbon impurity concentration in the TaSi film is less than specified detection limit (1E19 (atoms/cm³)). Thus, by using diethylsilane as the silicon source, the carbon impurity concentration in the metal silicide film can significantly be reduced.

The above reduction effect of the impurity concentration is due to high decomposition efficiency of the hydrocarbon silicon compound. In the case where the conventional silicon source is used, since the decomposition efficiency thereof is low, carbon bonded to silicon are not decomposed but taken in the metal silicide film. As a result, the impurity concentration in the metal silicide film is increased. On the other hand, in the present embodiment, the hydrocarbon silicon compound having a high decomposition efficiency is used, so that the impurity is easily gasified and removed. As a result, it is possible to significantly reduce the impurity concentration in the metal silicide film.

Further, the silicon ratio (silicon composition) in a TaSiN film as the metal silicide film was measured. In the case where silane having a low decomposition efficiency is used as the silicon source to form TaSiN, the silicon ratio in the TaSiN is less than 5%. Thus, the composition controllable range of silicon is very narrow. On the other hand, in the case where diethylsilane is used as the silicon source, it is possible to increase the silicon ratio in the metal silicide film up to about 90%, thus significantly widening the silicon composition controllable range.

As described above, in the present embodiment, as the silicon source used in the formation of the metal silicide film, a first hydrocarbon silicon compound obtained by replacing at least one of the hydrogen atoms in monosilane with an alkyl group, a second hydrocarbon silicon compound obtained by replacing at least one of the hydrogen atoms in disilane with an alkyl group, or a third hydrocarbon silicon compound obtained by replacing at least one of the hydrogen atoms in trisilane with an alkyl group is used. These hydrocarbon silicon compounds have a high decomposition efficiency. Therefore, it is possible to prevent the impurity such as carbon contained in the silicon source from being introduced into the metal silicide film. This prevents the controllability of the work function of the gate electrode from being degraded, thereby obtaining a semiconductor device excellent in characteristics and reliability.

Further, since the hydrocarbon silicon compound having a high decomposition efficiency is used as the silicon source in the present embodiment, it is possible to increase the silicon concentration (silicon ratio) in the metal silicide film as compared to a conventional approach, thereby making it possible to set the composition ratio between silicon and a metal element in the metal silicide film to a desired value. Therefore, a metal silicide film having desired and adequate characteristics can be formed. Also based on this standpoint, it is possible to obtain a semiconductor device excellent in characteristics and reliability.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising:
forming a gate insulating film on a semiconductor substrate; and
forming a gate electrode on the gate insulting film,
wherein forming the gate insulating film includes forming a metal silicate film, and
a silicon source used for forming the metal silicate film includes at least one of a first hydrocarbon silicon compound obtained by replacing at least one of hydrogen atoms in monosilane with an alkyl group, a second hydrocarbon silicon compound obtained by replacing at least one of hydrogen atoms in disilane with an alkyl group, and a third hydrocarbon silicon compound obtained by replacing at least one of hydrogen atoms in trisilane with an alkyl group.

2. The method according to claim 1, wherein
the metal silicate film is formed by a reaction between the silicon source, a metal source, and an oxidizer.

3. The method according to claim 2, wherein
the metal source is selected from an amine compound, a halogen compound, and an alkoxide compound.

4. The method according to claim 2, wherein
the oxidizer is selected from oxygen (O₂), ozone (O₃), nitric oxide (NO), nitrous oxide (N₂O), and an oxygen radical.

5. The method according to claim 1, wherein
the metal silicate film is formed using a CVD or ALD method.

6. The method according to claim 1, wherein
the metal silicate film contains a metal element selected from hafnium (Hf), zirconium (Zr), aluminum (Al), tantalum (Ta), and lanthanum (La).

7. The method according to claim 1, wherein
forming the gate insulating film includes applying a nitriding process to the metal silicate film.

8. The method according to claim 7, wherein
the nitriding process is selected from a plasma nitriding process, a thermal nitriding process and a radical nitriding process.

9. The method according to claim 1, wherein
the metal silicate film includes a lower part having a first metal concentration and an upper part having a second metal concentration lower than the first metal concentration.

10. The method according to claim 1, wherein
the first hydrocarbon silicon compound is selected from monomethylsilane, dimethylsilane, trimethylsilane, tetramethylsilane, monoethylsilane, diethylsilane, triethylsilane, tetraethylsilane, monopropylsilane, dipropylsilane, tripropylsilane, tetrapropylsilane, monobutylsilane, dibutylsilane, tributylsilane, and tetrabutylsilane.

11. A method of manufacturing a semiconductor device, comprising:
forming a gate insulating film on a semiconductor substrate; and
forming a gate electrode on the gate insulting film,
wherein forming the gate electrode includes forming a metal silicide film, and
a silicon source used for forming the metal silicide film includes at least one of a first hydrocarbon silicon compound obtained by replacing at least one of hydrogen atoms in monosilane with an alkyl group, a second hydrocarbon silicon compound obtained by replacing at least one of hydrogen atoms in disilane with an alkyl group, and a third hydrocarbon silicon compound obtained by replacing at least one of hydrogen atoms in trisilane with an alkyl group.

12. The method according to claim 11, wherein
the metal silicide film is formed by a reaction between the silicon source and a metal source or a reaction between the silicon source, a metal source, and a nitrogen source.

13. The method according to claim 12, wherein
the metal source is selected from an amine compound and a halogen compound.

14. The method according to claim 11, wherein
the metal silicide film is formed using a CVD or ALD method.

15. The method according to claim 11, wherein
the metal silicide film contains nitrogen.

16. The method according to claim 11, wherein
the metal silicide film contains a metal element selected from hafnium (Hf), zirconium (Zr), tantalum (Ta), titanium (Ti), ruthenium (Ru), and tungsten (W).

17. The method according to claim 11, wherein
the first hydrocarbon silicon compound is selected from monomethylsilane, dimethylsilane, trimethylsilane, tetramethylsilane, monoethylsilane, diethylsilane, triethylsilane, tetraethylsilane, monopropylsilane, dipropylsilane, tripropylsilane, tetrapropylsilane, monobutylsilane, dibutylsilane, tributylsilane, and tetrabutylsilane.
